(19) United States
(12) Patent Application Publication
(10) Pub. No.: US 2006/0103414 A1
(43) Pub. Date: May 18, 2006

(54) Method of inspecting array substrate

(76) Inventor: Satoru Tomita, Kawagoe-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/292,373

(22) Filed: Dec. 2, 2005

Related U.S. Application Data
(63) Continuation of application No. PCT/JP04/07993, filed on Jun. 2, 2004.

(30) Foreign Application Priority Data
Jun. 4, 2003 (JP) 2003-159436

(51) Int. Cl. G01R 31/00

(52) U.S. Cl. 324/770

(57) ABSTRACT

A method of inspecting an array substrate comprising supplying the driving circuit section with an electrical signal to drive the driving circuit section and electrically charge the pixel electrode, irradiating the electrically charged pixel electrode with an electron beam, and inspecting the pixel electrode based on information of a secondary electron emitted from the pixel electrode irradiated with the electron beam, wherein the electrical signal is supplied to the driving circuit section through the electrical signal supply pad, and the electrical signal is supplied from the electrical signal supply pad to different regions in the driving circuit section.

### CROSS-REFERENCE TO RELATED APPLICATIONS

This is a Continuation Application of PCT Application No. PCT/JP2004/007993, filed Jun. 2, 2004, which was published under PCT Article 21(2) in Japanese.

This application is based upon and claims the benefit of priority from prior Japanese Patent Application No. 2003-159436, filed Jun. 4, 2003, the entire contents of which are incorporated herein by reference.

### BACKGROUND OF THE INVENTION

1. Field of the Invention

This invention relates to a method of inspecting an array substrate that is a component of a liquid crystal display panel.

2. Description of the Related Art

A liquid crystal display panel is used in various display units such as a display unit of a notebook personal computer (notebook PC), that of a cellular phone, and that of a television set. The liquid crystal display panel includes array substrate in which a plurality of pixel electrodes are arranged in matrix, opposed substrate having opposed electrode opposed to the pixel electrodes, and a liquid crystal layer held between each of the array substrates and its opposed substrate.

The array substrate has a plurality of pixel electrodes arranged in matrix, a plurality of scanning lines arranged along the rows of the pixel electrodes, a plurality of signal lines arranged along the columns of the pixel electrodes, and a plurality of switching elements arranged close to the intersections of the scanning lines and the signal lines.

There are two types of array substrate: an array substrate whose switching elements are thin film transistors using semiconductor thin films of amorphous silicon, and an array substrate whose switching elements are thin film transistors using semiconductor thin films of polysilicon. The carrier mobility of polysilicon is higher than that of amorphous silicon. The array substrate of a polysilicon type can incorporate not only switching elements for pixel electrodes but also driving circuits for scanning and signal lines.

The above array substrate is supposed to undergo an inspection step in order to detect a defective product in the manufacturing process. Jpn. Pat. Appln. KOKAI Publication No. 11-271177, Jpn. Pat. Appln. KOKAI Publication No. 2000-3142 and U.S. Pat. No. 5,268,638 disclose an inspection method and an inspecting apparatus.

Jpn. Pat. Appln. KOKAI Publication No. 11-271177 discloses a technique that is featured in a point defect inspection process in inspection of amorphous type LCD substrates. In this technique, a direct light beam having DC components is applied to the entire surface of an LCD substrate, and an amorphous silicon film senses the light beam to bring the LCD substrate into a conductive state. Detecting an amount of leakage of charges stored in an auxiliary capacitor, the state of a defect can be determined. In the technique disclosed in Jpn. Pat. Appln. KOKAI Publication No. 2000-3142, when an electron beam is applied to a pixel electrode, the emitted secondary electron is proportionate to the voltage irradiated to a thin film transistor. In the technique of U.S. Pat. No. 5,268,638, too, when an electron beam is irradiated to a pixel electrode, the secondary electron is emitted.

The product price of a liquid crystal display panel is greatly influenced by the costs of manufacturing facilities thereof. The above-described inspection method and inspecting apparatus are essential to the manufacturing facilities, and very high costs are required for changing and modifying the design of the inspecting apparatus.

This invention has been developed in consideration of the above and its object is to provide a method of inspecting an array substrate that can reduce the occasions to change and modify the design of an inspecting apparatus to thereby prevent a liquid crystal display panel from increasing in product price.

### BRIEF SUMMARY OF THE INVENTION

In order to attain the above object, according to an aspect of the present invention, there is provided a method of inspecting an array substrate which comprises a substrate, a scanning line formed on the substrate, a signal line formed to intersect the scanning line, a switching element formed close to an intersection of the scanning line and the signal line, a pixel electrode connected to the switching element, a driving circuit section including at least one of a scanning line driving circuit which is formed on the substrate to supply the scanning line with a drive signal and a signal line driving circuit which supplies the signal line with a drive signal, and an electrical signal supply pad formed on the substrate, the method comprising: supplying different regions in the driving circuit section with an electrical signal through the electrical signal supply pad to drive the driving circuit section and electrically charge the pixel electrode; irradiating the electrically charged pixel electrode with an electron beam; and inspecting whether or not the array substrate is defective based on information of a secondary electron emitted from the pixel electrode irradiated with the electron beam.

Additional advantages of the invention will be set forth in the description which follows, and in part will be obvious from the description, or may be learned by practice of the invention. The advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a flowchart illustrating a method of inspecting an array substrate;

FIG. 2 is a schematic sectional view of a liquid crystal display panel having an array substrate;

FIG. 3 is a perspective view showing part of the liquid crystal display panel shown in FIG. 2;

FIG. 4 is a plan view showing an example of arrangement of array substrates formed using a mother substrate;

FIG. 5 is a schematic plan view of an array substrate main region of each of the array substrates shown in FIG. 4;

FIG. 6 is an enlarged schematic plan view of part of a pixel region of the array substrate shown in FIG. 5;

FIG. 7 is a schematic sectional view of a liquid crystal display panel with the array substrate shown in FIG. 6;

FIG. 8 is a schematic diagram of an inspecting apparatus for array substrates including an electron beam tester;

FIG. 9 is a plan view showing an example of an end portion of an array substrate to be inspected; and

FIG. 10 is a schematic plan view showing a remodeled example of the array substrate main region of the array substrate.

### DETAILED DESCRIPTION OF THE INVENTION

A method of inspecting array substrates, according to an embodiment of the invention, will be described with reference to the drawings. First, a liquid crystal display panel having polysilicon type array substrates will be described. An array substrate 101 will be described as one of the polysilicon type array substrates according to the present embodiment.

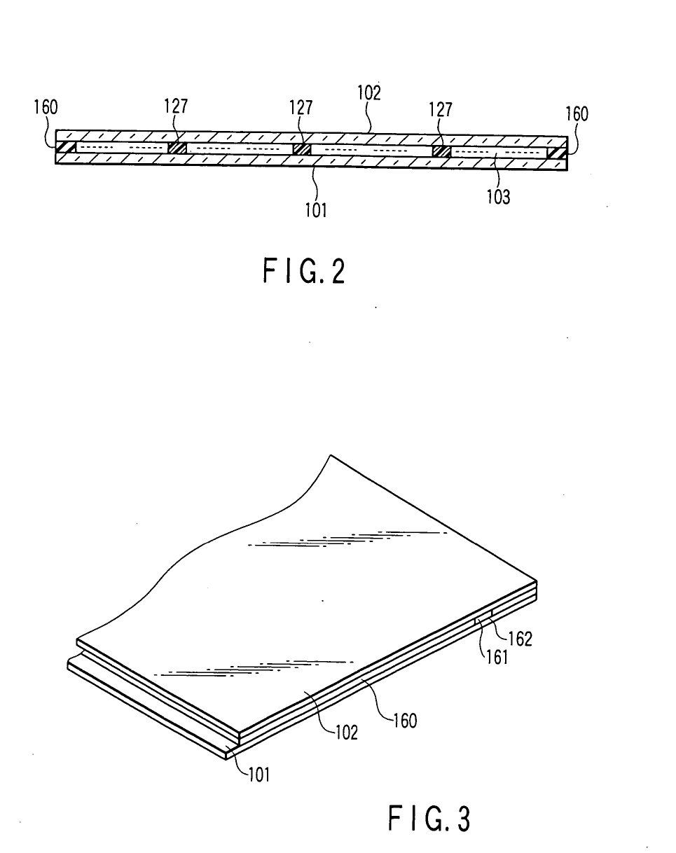

As shown in FIGS. 2 and 3, a liquid crystal display panel includes an array substrate 101, an opposed substrate 102 arranged opposite to the array substrate with a given gap therebetween, and a liquid crystal layer 103 sandwiched between both the substrates. Between the array substrate 101 and the opposed substrate 102, a given gap is maintained by a columnar spacer 127 as a spacer. The array substrate 101 and the opposed substrate 102 are bonded together at their edge portions with a sealing member 160. A liquid crystal injection port 161 is formed in part of the sealing member 160 and sealed with a sealant 162.

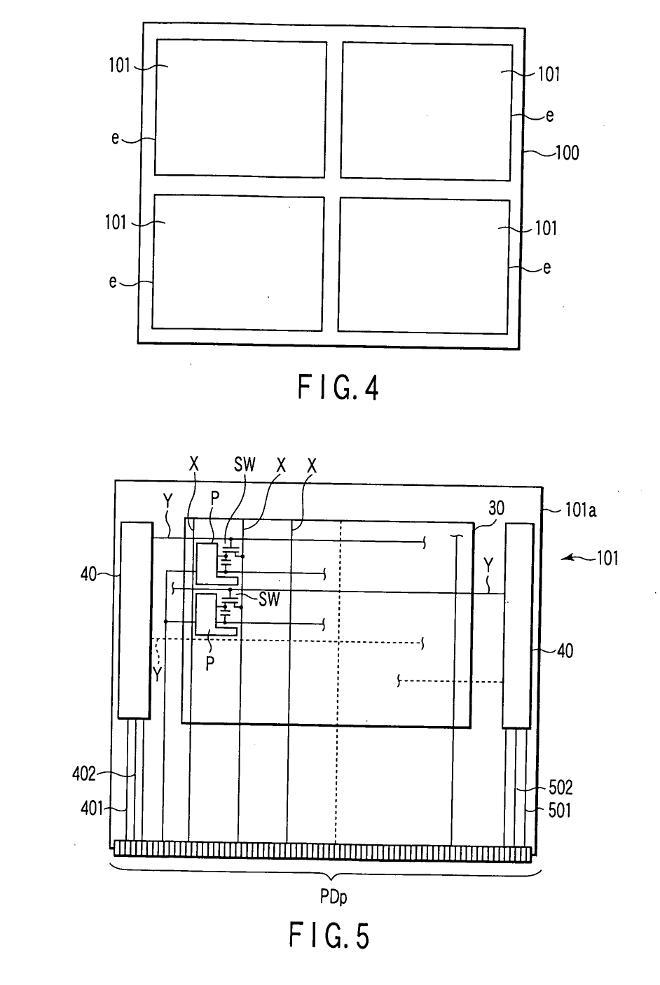

The array substrate 101 will be described in detail with reference to FIG. 4. FIG. 4 shows a mother substrate 100 the size of which is larger than that of the array substrate. In the example of FIG. 4, four array substrates 101 are configured using the mother substrate. The array substrates 101 are generally formed using the mother substrate 100.

The configuration of the array substrate 101 shown in FIG. 4 will be described as a typical one. The array substrate 101 includes an array substrate main region 101a and an array substrate sub-region 101b. Here is a detailed description of the array substrate main region 101a. The array substrate sub-region 101b will be described in detail later.

As illustrated in FIG. 5, a pixel region 30 on the array substrate 101 has a plurality of pixel electrodes P arranged in matrix. The array substrate 101 includes not only the pixel electrodes P but also a plurality of scanning lines Y arranged along the row of the pixel electrodes P and a plurality of signal lines X arranged along the column of the pixel electrodes P. The array substrate 101 includes a thin-film transistor (hereinafter referred to as TFT) SW serving as a switching element that is provided close to each of intersections of the scanning lines and the signal lines. The array substrate 101 includes scanning line driving circuits 40 to drive the scanning lines Y as a driving circuit section.

The scanning line driving circuits 40 are formed on the substrate. In the present embodiment, the scanning line driving circuits 40 are arranged on right and left sides of the pixel region 30. For example, the scanning lines Y of odd-numbered rows are connected to the left-side scanning line driving circuit 40, and the scanning lines Y of even-numbered rows are connected to the right-side scanning line driving circuit 40.

The TFT SW applies a signal voltage of a signal line to a pixel electrode P when it is driven through a scanning line Y. The scanning line driving circuits 40 are formed on the array substrate 101 and arranged outside the pixel region 30. Furthermore, the scanning line driving circuits 40 are configured using a TFT having a polysilicon semiconductor film like the TFT SW.

The array substrate 101 includes a pad group PDₚ that is arranged along one edge line of the array substrate main region 101 and has a plurality of terminals connected to the scanning line driving circuits 40 and the signal lines X. The pad group PDₚ is used to input different signals and input/output signals for inspection. The array substrate 101 is separated from other substrates by cutting the mother substrate 100 along the edges e (FIG. 4) of the array substrates.

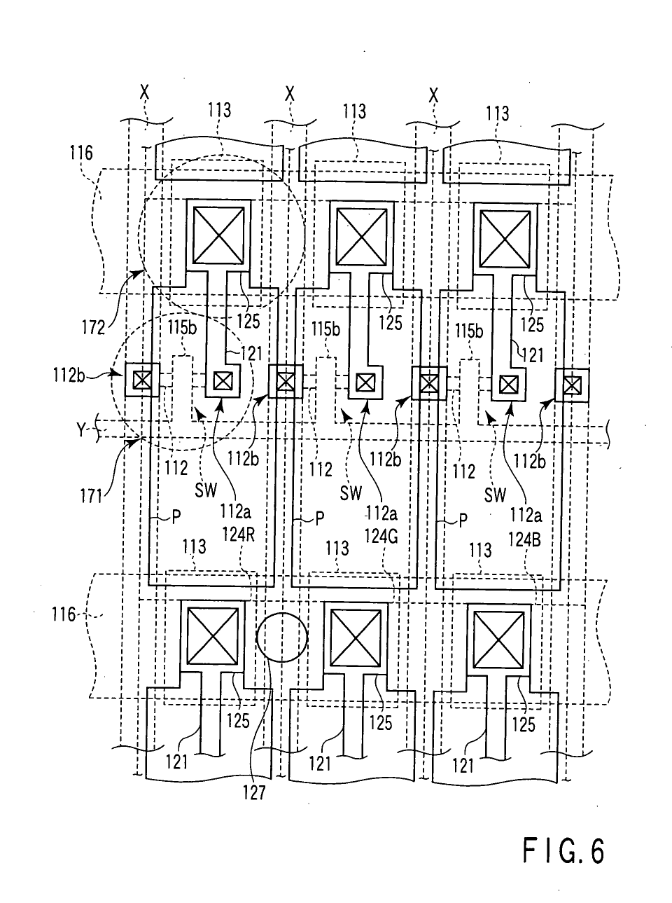

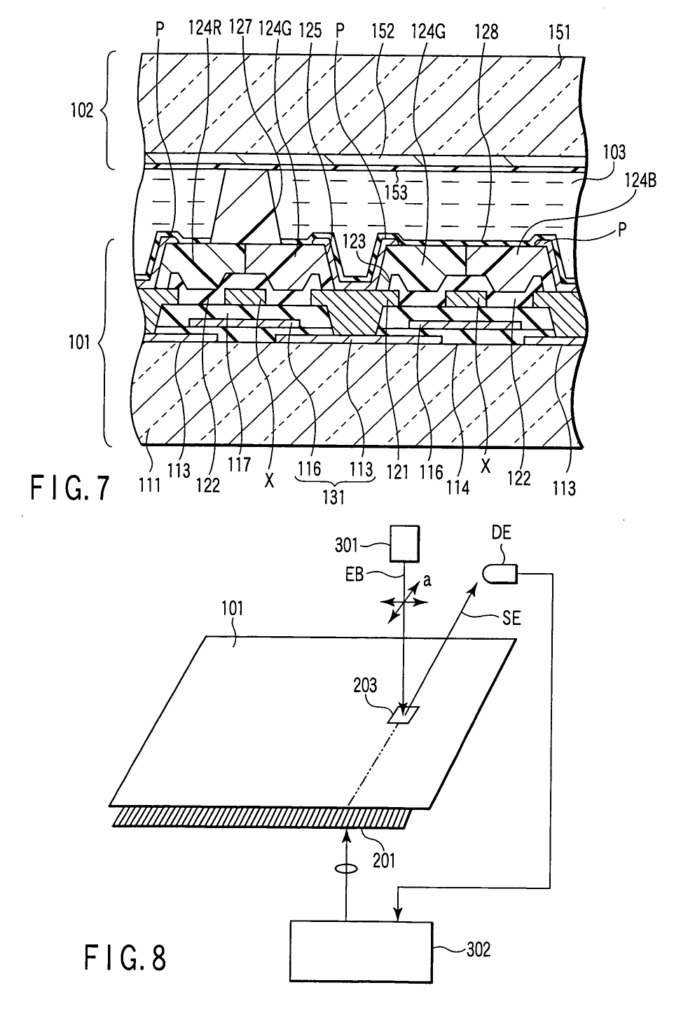

The pixel region 30 of the liquid crystal display panel will be described further by extracting its part therefrom with reference to FIGS. 6 and 7. FIG. 6 is an enlarged plan view of the pixel region 30 of the array substrate, and FIG. 7 is an enlarged sectional view of the pixel region of the liquid crystal display panel. The array substrate 101 includes a substrate 111 as a transparent insulation substrate such as a glass substrate. A plurality of signal lines X and a plurality of scanning lines Y are arranged in matrix on the substrate 111, and a TFT SW (see the portion surrounded by circle 171 in FIG. 6) is provided close to each of intersections of the signal lines and scanning lines.

The TFT SW includes a semiconductor film 112 having source/drain regions 112a and 112b formed of polysilicon and a gate electrode 115b that corresponds to an elongated portion of a scanning line Y.

A plurality of auxiliary capacitive lines 116 are formed in a striped manner on the substrate 111 to form auxiliary capacitive elements 131, and extend in parallel with the scanning lines Y. A pixel electrode P is formed in this section (see the portion indicated by circle 172 in FIG. 6 and FIG. 7).

If described in detail, semiconductor films 112 and auxiliary capacitive lower electrodes 113 are formed on the substrate 111, and a gate insulation film 114 is deposited on the substrate including the semiconductor films and the auxiliary capacitive lower electrodes. Like the semiconductor film 112, the auxiliary capacitive lower electrodes 113 are formed of polysilicon. Scanning lines Y, gate electrodes 115b and auxiliary capacitive lines 116 are formed on the gate insulation film 114. The auxiliary capacitive lines 116 and auxiliary capacitive lower electrodes 113 are arranged opposite to each other with the gate insulation film 114 therebetween. An interlayer insulation film 117 is deposited on the gate insulation film 114 including the scanning lines Y, gate electrodes 115b and auxiliary capacitive lines 116.

Contact electrodes 121 and signal lines X are formed on the interlayer insulation film 117. Each contact electrode 121 is connected through a respective contact hole to the source/drain region 112a of the respective semiconductor film 112 and the pixel electrode P. The contact electrode 121 is connected to the auxiliary capacitive lower electrode 113. Each signal line X is connected to the source/drain region 112b of the respective semiconductor film 112 through a respective contact hole.

A protecting insulation film 122 is formed on the contact electrodes 121, signal lines X and interlayer insulation film 117. Further, green-colored layers 124 G, red-colored layers 124R and blue-colored layers 124B are arranged adjacent to each other in a striped manner on the protecting insulation film 122. The colored layers 124G, 124R and 124B make up a color filter.

The pixel electrodes P are formed on their respective colored layers 124G, 124R and 124B by transparent conductive film such as ITO (indium tin oxide). Each of the pixel electrodes P is connected to the contact electrode 121 through a contact hole 125 formed in the colored layers and protecting insulation film 122. The peripheries of the pixel electrodes P overlap the auxiliary capacitive lines 116 and signal lines X. The auxiliary capacitive element 131 connected to the pixel electrode P functions as auxiliary capacitor store electric charge.

The columnar spacer 127 (see FIG. 6) is formed on the colored layers 124R and 124G. A plurality of columnar spacers 127 are formed on each of the colored layers at a desired density though all of them are not shown. An alignment film 128 is formed on the colored layers 124G, 124R and 124B and the pixel electrodes P. The opposed substrate 102 has a substrate 151 as a transparent insulation substrate. An opposed electrode 152 made of transparent material such as an ITO and an alignment film 153 are formed in sequence on the substrate 151.

A method of inspecting the array substrates 101 using an electron beam tester (hereinafter referred to an EB tester) will be described with reference to FIG. 8. This inspection is performed after the pixel electrodes P are formed on the substrates and before the array substrates 101 are cut out of the mother substrate 100 along their edges e.

First, the configuration of an inspecting apparatus used for inspecting the array substrates 101 will be described. An EB tester is provided for the inspecting apparatus. A plurality of probes connected to a signal generator and signal analyzer 302 are connected to a plurality of pads 201 corresponding thereto. The drive signals serving as electrical signals output from the signal generator and signal analyzer 302 are supplied to the pixel sections 203 through the probes and the pads 201 to electrically charge the pixel electrodes P. After the drive signals are supplied to the pixel section 203, the pixel electrode P of the pixel section is irradiated with an electron beam EB from an electron beam source 301. With this irradiation, a secondary electron SE that represents the voltage of the pixel electrodes P is emitted and detected by an electron detector DE. The secondary electron SE is proportionate to the voltage of an area from which the electron is emitted. Information of the secondary electron detected by the electron detector DE is sent to the signal generator and signal analyzer 302 in order to analyze the pixel section 203. The information of the secondary electron indicates the state of the pixel section 203. It is thus possible to inspect the pixel electrode P of each pixel section 203. In other words, when the pixel section 203 is defective, the EB tester can detect the defect. The defect of the pixel section 203 means not only a defect of a pixel electrode P in itself but also a defect of an element associated with the pixel electrode, such as a defect of a TFT SW connected to the pixel electrode P and a defect of an auxiliary capacitive element 131 including the pixel electrode P.

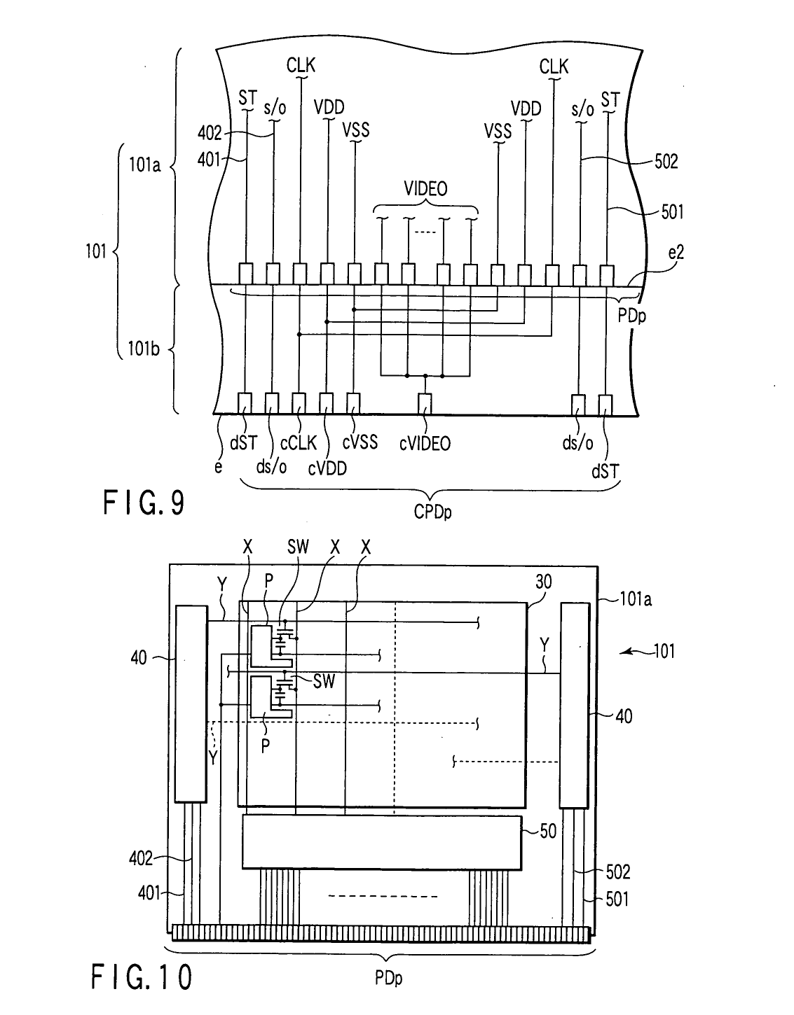

FIG. 9 shows an example of an end portion of an array substrate 101 to be inspected. The array substrate 101 includes an array substrate main region 101a and an array substrate sub-region formed outside the array substrate main region. The array substrate sub-region 101b is inspected and then cut out by drawing, e.g., a scribe line along a tear-off line e2.

The pad group PDₚ of the array substrate main region 101a is connected to the scanning line driving circuits 40 and signal lines X shown in FIG. 5 through wirings. The terminals that configure the pad group PDₚ arranged in this region are classified into a logic terminal, a power supply terminal, an inspection terminal and a signal input terminal.

The logic terminal has terminals CLK and terminals ST. The signals input to the terminals CLK and ST are a clock signal and a start pulse signal. The clock signal and start pulse signal are signals input to the scanning line driving circuits 40. In the present embodiment, since the scanning line driving circuits 40 are arranged on right and left sides of the pixel region 30, the pad group PDₚ includes two terminals ST, two terminals CLK and the like.

The inspection terminal includes serial-out terminals s/o. There are two serial-out terminals s/o like the clock terminals CLK and the start pulse terminals ST. The signals output from the serial-out terminals s/o are serial outputs of shift registers (s/r) of the scanning line driving circuits 40 that respond to a start pulse signal.

The power supply terminal is divided into terminals VDD and VSS. The signals input to the terminals VDD and VSS are a high-level power supply and a low-level power supply. There are two terminals VDD and two terminals VSS like the terminals CLK. The signal input terminal includes terminals VIDEO. The signals input to the terminals VIDEO are, for example, video signals. The number of terminals VIDEO is several hundreds to several thousands and they have a large share of the pad group PDₚ.

A connection pad group CPDₚ is provided at the edge of the array substrate sub-region 101b. The connection pad group CPDₚ includes a plurality of electrical signal supply pads and is connected to the pad group PDₚ of the array substrate main region 101a through wirings. The drive signals are supplied from the electrical signal supply pads to different regions in the scanning line driving circuits 40. The drive signals include a high-level power supply and a low-level power supply as well as a clock signal and a start pulse signal.

The pad group PDₚ is divided by the terminal to which the same or same type signal is supplied, and includes a plurality of terminal groups. A common connection pad group CPDₚ is prepared for each of the terminal groups. The terminals to which the same signal is input are roughly divided into a logic terminal, a power supply terminal, an inspection terminal and a signal input terminal. The common terminals are a clock common terminal cCLK, a high-level common terminal cVDD, a low-level common terminal cVSS and a video signal common terminal cVIDEO. These common terminals cCLK, cVDD, cVSS and cVIDEO are arranged at the edge e of the array substrate sub-region 101b and connected to the pad group PDₚ of the corresponding array substrate main region 101a through wirings.

A relationship in connection between the above-described connection pad group CPDₚ and pad group PDₚ will be described in detail. The terminals ST and s/o of the array substrate main region 101a are connected to their respective dependent terminals dST and ds/o of the array substrate sub-region 101b through wirings. Since the terminals CLK of the array substrate main region 101a belong to the same group, they are connected to the common terminal cCLK. Since the terminals VDD of the array substrate main region 101a belong to the same group, they are connected to the common terminal cVDD. Since the terminals VSS of the array substrate main region 101a belong to the same group, they are connected to the common terminal cVSS. Since the terminals VIDEO of the array substrate main region 101a belong to the same group, they are connected to the common terminal cVIDEO of the array substrate sub-region 101b.

The terminals VIDEO are connected to one common terminal cVIDEO, but they can be connected to a small number of common terminals. Thus, the number of pads of the connection pad group CPDₚ provided in the array substrate sub-region 101b is greatly reduced as compared with the number of pads of the pad group PDₚ provided in the array substrate main region 101a.

When the pixel sections 203 of the array substrate 101 so configured are inspected by the EB tester, probes are connected to each of pads of the connection pad group CPDₚ of the array substrate 101 and the scanning line driving circuits 40 are supplied with drive signals through the probes. Thus, the scanning line driving circuits 40 are operated to store electric charges in the auxiliary capacitors of the pixel sections 203. In other words, the pixel electrodes P are electrically charged. After the charges are stored, the pixel electrodes P of the pixel sections 203 are irradiated with an electron beam. The secondary electrons emitted from the pixel electrodes P irradiated with the electron beam are detected. It is thus inspected whether the pixel sections 203 are defective or not.

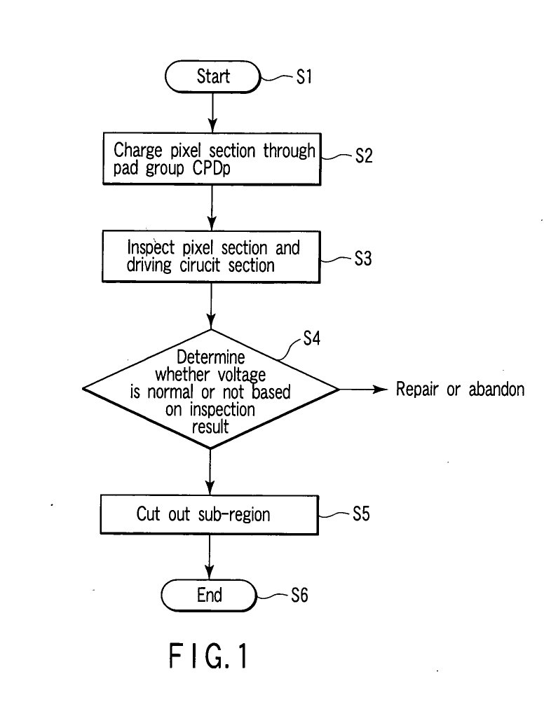

FIG. 1 schematically shows a process of inspecting the array substrate 101 described above. When an inspection starts (step S1), an array substrate 101 is carried into a vacuum chamber not shown, and auxiliary capacitors of the pixel sections 203 are electrically charged through the pad group CPDₚ (step S2). Then, the EB tester scans over the pixel sections 203 to measure the emitted secondary electron (step S3) and determine whether the voltage of the pixel section is normal or not (step S4). The scanning line driving circuits 40 can be inspected (step S3). The inspection of the scanning line driving circuits 40 can be electrically performed. In other words, the electrical signals, which are supplied from the pads and flow through the scanning line driving circuits 40, are output from the terminal s/o, and the output signals are analyzed to allow the scanning line driving circuits to be inspected. The inspection of the pixel sections 203 and that of the scanning line driving circuits 40 can be performed at the same time or in sequence. When they are done in sequence, the scanning line driving circuits 40 are inspected first. If a defect occurs, the subsequent inspection can be omitted and accordingly the inspection time can be shortened. When a defective array substrate 101 is detected, it is repaired or abandoned. When a defect-free array substrate 101 is detected, it is sent to the next step, where an array substrate sub-region 101b is cut out of the array substrate 101 (step S5). The inspection ends (step S6).

According to the above-described method and apparatus for inspecting array substrates, the number of pads of the connection pad group CPDₚ is small and so is the number of probes of the inspecting apparatus. The costs for the inspecting apparatus are lowered to allow a good inspection.

The arrangement of the terminals of the connection pad group CPDₚ conforms to that of the probes. Therefore, even though the pad group PDₚ of the array substrate main region 101a and the arrangement of the pads thereof are changed, the connection pad group CPDₚ can be forced to be formed such that its arrangement conforms to that of probes of the inspecting apparatus. If, therefore, the inspecting apparatus and the array substrates are combined elaborately, the inspecting apparatus can be increased in flexibility. As described above, there can be provided a method of inspecting array substrates that can reduce the occasions to change and modify the design of an inspecting apparatus to thereby prevent a liquid crystal display panel from increasing in product price.

Even though the design of the circuit arrangement of the array substrate main region 101a is changed, the design of the inspecting apparatus need not be changed or modified by maintaining the same arrangement of the pad group CPDₚ of the array substrate sub-region 101b.

If the array substrate 101 is inspected using the EB tester, it is possible to discover whether the pixel sections 203 are defective or not. The product drain of defective liquid crystal display panels can thus be suppressed.

This invention is not limited to the above-described embodiment, but various modifications can be made within the scope of the invention. For example, as shown in FIG. 10, scanning line driving circuits 40 serving as a driving circuit section and a signal line driving circuit for driving a plurality of signal lines can be formed in the region outside the pixel region 30 on the array substrate 101. The signal line driving circuit 50 is configured using a TFT having a polysilicon semiconductor film like the TFT SW.

The signal line driving circuit 50 is connected to the connection pad group CPDₚ through the pad group PDₚ. The video signals serving as electrical signals supplied to the electrical signal supply pads that make up the connection pad group CPDₚ are supplied from the electrical signal supply pads to different regions in the signal line driving circuit 50. The connection pad group CPDₚ includes a logic terminal and an inspection terminal, which are connected to the signal line driving circuit 50. When a video signal, a clock signal and a start pulse signal are input to the signal line driving circuit 50, the shift registers that configure the signal line driving circuit 50 are driven and the signals are output from the shift registers. It is thus determined whether the signal line driving circuit 50 is normal or not according to the analysis of the output signals.

As described above, the scanning line driving circuits 40 and signal line driving circuit 50 can electrically be inspected. Applying a driving signal to the scanning line driving circuits 40 and signal line driving circuit 50, the pixel electrodes P can electrically be charged. Therefore, it is possible to inspect it with electron beam as described above.

The array substrate 101 to be inspected is formed on the substrate and may have a driving circuit including at least one of the scanning line driving circuit 40 that supplies a driving signal to the scanning lines Y and a signal line driving circuit 50. The TFTs that make up the scanning line driving circuit 40 and signal line driving circuit 50 need not include polysilicon.

What is claimed is:

1. A method of inspecting an array substrate which comprises a substrate, a scanning line formed on the substrate, a signal line formed to intersect the scanning line, a switching element formed close to an intersection of the scanning line and the signal line, a pixel electrode connected to the switching element, a driving circuit section including at least one of a scanning line driving circuit which is formed on the substrate to supply the scanning line with a drive signal and a signal line driving circuit which supplies the signal line with a drive signal, and an electrical signal supply pad formed on the substrate, the method comprising:
supplying different regions in the driving circuit section with an electrical signal through the electrical signal supply pad to drive the driving circuit section and electrically charge the pixel electrode;
irradiating the electrically charged pixel electrode with an electron beam; and
inspecting whether or not the array substrate is defective based on information of a secondary electron emitted from the pixel electrode irradiated with the electron beam.

2. The method of inspecting an array substrate according to claim 1, wherein the switching element and the driving circuit section each include a transistor using polysilicon.

3. The method of inspecting an array substrate according to claim 1, wherein the electrical signal is a clock signal.

4. The method of inspecting an array substrate according to claim 1, wherein the electrical signal is a start pulse signal.

5. The method of inspecting an array substrate according to claim 1, wherein the driving circuit section includes a plurality of scanning line driving circuits formed on the substrate, and the supplying the electrical signal includes supplying different regions in the respective scanning line driving circuits with the electrical signal.
